(19) United States
(12) Patent Application Publication
(10) Pub. No.: US 2024/0030118 A1
(43) Pub. Date: Jan. 25, 2024

(54) PACKAGE SUBSTRATE AND SEMICONDUCTOR PACKAGE INCLUDING THE SAME

(71) Applicant: SAMSUNG ELECTRONICS CO., LTD., Suwon-si (KR)

(72) Inventor: Myungsam KANG, Suwon-si (KR)

(73) Assignee: SAMSUNG ELECTRONICS CO., LTD., Suwon-si (KR)

(21) Appl. No.: 18/224,948

(22) Filed: Jul. 21, 2023

(30) Foreign Application Priority Data
Jul. 21, 2022 (KR) 10-2022-0090614

(51) Int. Cl. H01L 23/498; H01L 23/15; H01L 25/065; H01L 23/48

(52) U.S. Cl. CPC H01L 23/49822; H01L 23/15; H01L 28/60; H01L 23/49811; H01L 25/0652; H01L 23/481; H01L 2224/16145; H01L 2224/16227; H01L 24/16

(57) ABSTRACT

A package substrate includes a ceramic substrate including a plurality of first insulating layers and a first circuit wiring layer disposed in the plurality of first insulating layers, a redistribution structure disposed on an upper surface of the ceramic substrate, and including a plurality of second insulating layers and a second circuit wiring layer disposed in the plurality of second insulating layers and electrically connected to the first circuit wiring layer, and a capacitor structure provided at an interface between the ceramic substrate and the redistribution structure, and including a lower electrode layer disposed at the same vertical level as at least a portion of the first circuit wiring layer, a dielectric layer disposed between the ceramic substrate and the redistribution structure, and an upper electrode layer disposed on an upper surface of the dielectric layer.

### CROSS-REFERENCE TO RELATED APPLICATION

This application is based on and claims priority under 35 U.S.C. § 119 to Korean Patent Application No. 10-2022-0090614, filed on Jul. 21, 2022, in the Korean Intellectual Property Office, the disclosure of which is incorporated by reference herein in its entirety.

### BACKGROUND

The present disclosure relates to a package substrate and a semiconductor package including the same, and more particularly, to a package substrate including a built-in capacitor and a semiconductor package including the package substrate.

As the electronics industry develops rapidly, in order to meet the needs of users, electronic devices are becoming smaller and lighter. Semiconductor packages used in electronic devices are required to have high performance and large capacity along with miniaturization and light weight. In order to obtain high performance and large capacity, along with miniaturization and light weight of semiconductor packages, research and development of a package substrate including a built-in capacitor and a semiconductor package including the package substrate has been conducted.

### SUMMARY

One or more example embodiments provide a package substrate for implementing a high-capacity capacitor and a semiconductor package including the package substrate.

Further, one or more example embodiments provide a method of manufacturing a package substrate for implementing a high-capacity capacitor.

According to an aspect of an example embodiment, a package substrate includes: a ceramic substrate including a plurality of first insulating layers and a first circuit wiring layer disposed in the plurality of first insulating layers; a redistribution structure disposed on an upper surface of the ceramic substrate, the redistribution structure including a plurality of second insulating layers and a second circuit wiring layer disposed in the plurality of second insulating layers and electrically connected to the first circuit wiring layer; and a capacitor structure provided at an interface between the ceramic substrate and the redistribution structure, the capacitor structure including a lower electrode layer disposed at a same vertical level as at least a portion of the first circuit wiring layer, a dielectric layer disposed between the ceramic substrate and the redistribution structure, and an upper electrode layer disposed on an upper surface of the dielectric layer.

According to an aspect of an example embodiment, a semiconductor package includes: a package substrate; an interposer disposed on the package substrate; and at least one semiconductor chip disposed on the interposer, wherein the package substrate includes: a ceramic substrate including a plurality of first insulating layers and a first circuit wiring layer disposed in the plurality of first insulating layers; a redistribution structure disposed on an upper surface of the ceramic substrate, the redistribution structure including a plurality of second insulating layers and a second circuit wiring layer disposed in the plurality of second insulating layers and electrically connected to the first circuit wiring layer; and a capacitor structure provided at an interface between the ceramic substrate and the redistribution structure, the capacitor structure including a lower electrode layer disposed at a same vertical level as at least a portion of the first circuit wiring layer, a dielectric layer disposed between the ceramic substrate and the redistribution structure, and an upper electrode layer disposed on an upper surface of the dielectric layer.

According to an aspect of an example embodiment, a semiconductor package includes: a package substrate; an interposer disposed on the package substrate; at least one first semiconductor chip disposed on the interposer; and at least one stacked structure disposed on the interposer, wherein the package substrate includes: a ceramic substrate including a plurality of first insulating layers and a first circuit wiring layer disposed in the plurality of first insulating layers; a redistribution structure disposed on an upper surface of the ceramic substrate, the redistribution structure including a plurality of second insulating layers and a second circuit wiring layer disposed in the plurality of second insulating layers and electrically connected to the first circuit wiring layer; and a capacitor structure provided at an interface between the ceramic substrate and the redistribution structure, the capacitor structure including a lower electrode layer disposed on a same vertical level as at least a portion of the first circuit wiring layer and including a first conductive material, a dielectric layer disposed between the ceramic substrate and the redistribution structure, and an upper electrode layer disposed on an upper surface of the dielectric layer and including a second conductive material different from the first conductive material, and wherein the at least one stacked structure includes: a second semiconductor chip including a through electrode and a plurality of third semiconductor chips stacked on the second semiconductor chip in a vertical direction, each of the third semiconductor chips including a through electrode.

According to an aspect of an example embodiment, a method of manufacturing a package substrate, includes: stacking a plurality of conductive sheets, each of the plurality of conductive sheets including a first insulating layer, a first wiring layer disposed on an upper surface of the first insulating layer, and a via disposed in a via hole passing through the first insulating layer; forming a ceramic substrate by sintering the plurality of conductive sheets, the ceramic substrate including a first circuit wiring layer and a lower electrode layer; forming a dielectric layer on the lower electrode layer of the ceramic substrate; forming an upper electrode layer on the dielectric layer; and forming a redistribution structure including a second circuit wiring layer on the dielectric layer and the upper electrode layer.

According to an aspect of an example embodiment, a method of manufacturing a semiconductor package, including: forming a package substrate; mounting at least one semiconductor chip on an interposer; and attaching the interposer, on which the at least one semiconductor chip is mounted, to the package substrate, wherein the forming the package substrate includes: stacking a plurality of conductive sheets, each of the plurality of conductive sheets including a first insulating layer, a first wiring layer disposed on an upper surface of the first insulating layer, and a via disposed in a via hole passing through the first insulating layer; forming a ceramic substrate by sintering the plurality of conductive sheets, the ceramic substrate including a first circuit wiring layer and a lower electrode layer; forming a dielectric layer on the lower electrode layer of the ceramic substrate; forming an upper electrode layer on the dielectric layer; and forming a redistribution structure including a second circuit wiring layer on the dielectric layer and the upper electrode layer.

### BRIEF DESCRIPTION OF THE DRAWINGS

The above and other aspects, features, and advantages of the present disclosure will be more clearly understood from the following detailed description of example embodiments taken in conjunction with the accompanying drawings, in which:

FIG. 1 is a cross-sectional view illustrating a package substrate according to an example embodiment;

FIG. 2 is an enlarged view of portion A of FIG. 1 according to an example embodiment;

FIG. 3 is a cross-sectional view illustrating a package substrate according to an example embodiment;

FIG. 4 is an enlarged view of part A of FIG. 3 according to an example embodiment;

FIG. 5 is a planar layout illustrating a semiconductor package according to an example embodiment;

FIG. 6 is a cross-sectional view of the semiconductor package taken along line B-B′ of FIG. 5 according to an example embodiment;

FIG. 7 is a flowchart illustrating a method of manufacturing a package substrate according to an example embodiment;

FIGS. 8, 9, 10, 11 and 12 are cross-sectional views illustrating a method of manufacturing a package substrate according to an example embodiment; and

FIG. 13 is a flowchart illustrating a method of manufacturing a semiconductor package according to an example embodiment.

### DETAILED DESCRIPTION

Hereinafter, example embodiments of are described in detail with reference to the accompanying drawings.

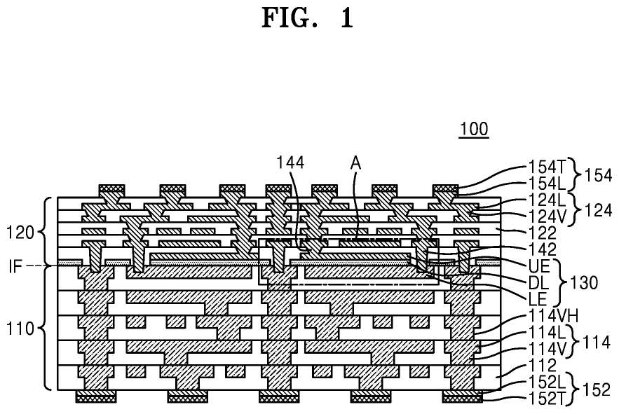

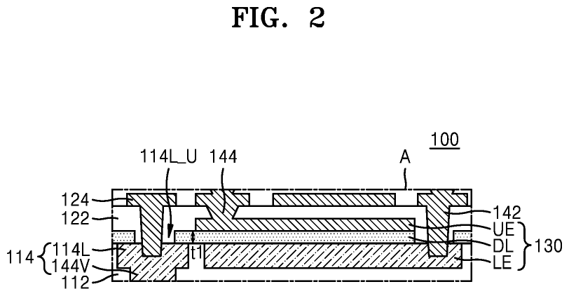

FIG. 1 is a cross-sectional view illustrating a package substrate 100 according to an example embodiment. FIG. 2 is an enlarged view of portion A of FIG. 1 according to an example embodiment.

Referring to FIGS. 1 and 2, the package substrate 100 may include a ceramic substrate 110, a redistribution structure 120, and a capacitor structure 130.

The ceramic substrate 110 may include a plurality of first insulating layers 112 and a first circuit wiring layer 114 disposed between or in the plurality of first insulating layers 112. In an example embodiment, the plurality of first insulating layers 112 may include a low-temperature fired dielectric or low-temperature sintered dielectric, for example, aluminum oxide (Al₂O₃).

The first circuit wiring layer 114 may include a first wiring layer 114L and a first via 114V. The first wiring layer 114L may extend in a horizontal direction between or in the plurality of first insulating layers 112 and may be disposed at a plurality of vertical levels. The first via 114V may be disposed inside a via hole 114VH passing through the plurality of first insulating layers 112, and may connect the plurality of first wiring layers 114L to each other between the plurality of first wiring layers 114L disposed at different vertical levels. In an example embodiment, the first wiring layer 114L and the first via 114V may include silver (Ag) or tungsten (W).

In an example embodiment, the ceramic substrate 110 may be formed by forming a first wiring layer 114L and the first via 114V constituting the first circuit wiring layer 114 on each of the plurality of first insulating layers 112, stacking the plurality of first insulating layers 112, and then forming by low temperature co-firing. For example, the co-firing temperature may range from about 700° C. to about 1100° C.

The redistribution structure 120 may be disposed on the ceramic substrate 110. The redistribution structure 120 may include a plurality of second insulating layers 122 and a second circuit wiring layer 124 disposed between or in the plurality of second insulating layers 122.

In an example embodiment, the plurality of second insulating layers 122 may include a polymer material, for example, a photo-imageable dielectric (PID), a photosensitive polyimide (PSPI), a glass fiber-cured epoxy resin, a polyimide resin, teflon resin, or the like.

The second circuit wiring layer 124 may include a second wiring layer 124L and a second via 124V. The second wiring layer 124L may extend in a horizontal direction between or in the plurality of second insulating layers 122 and may be disposed at a plurality of vertical levels. The second via 124V may connect the plurality of second wiring layers 124L to each other between the plurality of second wiring layers 124L disposed at different vertical levels. In an example embodiment, the second wiring layer 124L and the second via 124V may include at least one of copper (Cu), nickel (Ni), gold (Au), platinum (Pt), titanium (Ti), chromium (Cr), or an alloy thereof. The second circuit wiring layer 124 may be electrically connected to the first circuit wiring layer 114 of the ceramic substrate 110.

The capacitor structure 130 may be provided at the interface IF between the ceramic substrate 110 and the redistribution structure 120. The capacitor structure 130 may include a lower electrode layer (LE), a dielectric layer (DL), and an upper electrode layer (UE), and may be a planar thin film decoupling capacitor having a metal-insulator-metal (MIM) structure.

The lower electrode layer LE may be disposed at the same vertical level as that of at least a portion of the first circuit wiring layer 114. For example, the lower electrode layer LE may be disposed at the same vertical level as that of an uppermost first wiring layer 114L_U among the plurality of first wiring layers 114L. Here, the uppermost first wiring layer 114L_U may indicate the first wiring layer 114L disposed closest to the redistribution structure 120 among the plurality of first wiring layers 114L.

In an example embodiment, the lower electrode layer LE may include a first conductive material, and the first conductive material may include silver (Ag) or tungsten (W). The lower electrode layer LE may include the same material as the material constituting the first circuit wiring layer 114, and may be formed simultaneously in a process for forming the first circuit wiring layer 114. For example, the lower electrode layer LE may have a thickness in a range of about 3 micrometers to about 10 micrometers.

The dielectric layer DL may be disposed on the first circuit wiring layer 114 and the lower electrode layer LE on the ceramic substrate 110. In an example embodiment, the dielectric layer DL may include a high-k dielectric material. A high-k dielectric material may refer to a material having a dielectric constant greater than that of silicon oxide. In some example embodiments, the dielectric layer DL may include a material having a dielectric constant of about 5 or more, or about 10 or more. For example, the dielectric layer DL may include, but is not limited to, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

In an example embodiment, the dielectric layer DL may be formed using at least one of a chemical vapor deposition (CVD) process, a physical vapor deposition (PVD) process, and an atomic layer deposition (ALD) process, a spin coating process, and a spray process. The dielectric layer DL may have, for example, a thickness t1 of about 1 micrometer to about 5 micrometers. As the dielectric layer DL is formed using a high-k dielectric material and has a relatively thin thickness, the capacitor structure 130 may exhibit a relatively high capacitance.

The upper electrode layer UE may be disposed on the upper surface of the dielectric layer DL. The upper electrode layer UE may include a second conductive material, and the second conductive material may be different from the first conductive material. For example, the second conductive material may include at least one of copper (Cu), nickel (Ni), gold (Au), platinum (Pt), titanium (Ti), chromium (Cr), or an alloy thereof. The upper electrode layer UE may include the same material as the material constituting the second circuit wiring layer 124, and may be simultaneously formed in a process for forming the second circuit wiring layer 124. In an example embodiment, the upper electrode layer UE may be formed on the upper surface of the dielectric layer DL by using at least one of an electrolytic plating process, an electroless plating process, a sputtering process, and an evaporation process. For example, the upper electrode layer UE may have a thickness in a range of about 1 micrometer to about 10 micrometers.

The upper electrode layer UE of the capacitor structure 130 may include a second conductive material different from the first conductive material constituting the lower electrode layer LE. The upper electrode layer UE may be formed by an electrolytic plating process, an electroless plating process, a sputtering process, or an evaporation process in a process for forming the redistribution structure 120, and accordingly, may be formed to have a precise pattern shape according to required capacitance. Accordingly, misalignment between the lower electrode layer LE and the upper electrode layer UE may be prevented, and capacitance deviation of the capacitor structure 130 may be prevented.

The package substrate 100 may further include a first bump connection via 142 and a second bump connection via 144 electrically connected to the capacitor structure 130. The first bump connection via 142 may pass through the second insulating layer 122 to be electrically connected to the lower electrode layer LE, and an upper end of the first bump connection via 142 may be electrically connected to the second circuit wiring layer 124. The second bump connection via 144 may pass through the second insulating layer 122 to be electrically connected to the upper electrode layer UE. In an example embodiment, each of the first bump connection via 142 and the second bump connection via 144 may have a first width in a range of about 20 micrometers to about 60 micrometers.

The package substrate 100 may include a first pad 152 disposed on a lower surface of the ceramic substrate 110 and a second pad 154 disposed on an upper surface of the redistribution structure 120.

The first pad 152 may be electrically connected to the first circuit wiring layer 114 of the ceramic substrate 110, and may include a pad layer 152L and a capping metal layer 152T disposed on an outer surface of the pad layer 152L. For example, the pad layer 152L may include at least one of copper (Cu), nickel (Ni), gold (Au), platinum (Pt), titanium (Ti), chromium (Cr), or an alloy thereof, and the capping metal layer 152T may include at least one of nickel (Ni), gold (Au), platinum (Pt), or an alloy thereof. An external connection terminal (not shown), such as a solder ball having a relatively large size, may be disposed on the capping metal layer 152T of the first pad 152.

The second pad 154 may be electrically connected to the second circuit wiring layer 124 of the redistribution structure 120, and include a pad layer 154L and a capping metal layer 154T disposed on an outer surface of the pad layer 154L. For example, the pad layer 154L may include at least one of copper (Cu), nickel (Ni), gold (Au), platinum (Pt), titanium (Ti), chromium (Cr), or an alloy thereof, and the capping metal layer 154T may include at least one of nickel (Ni), gold (Au), platinum (Pt), or an alloy thereof. An external connection terminal (not shown), such as connection bumps having a relatively small size, may be disposed on the capping metal layer 154T of the second pad 154.

In general, when a package substrate based on the ceramic material is formed, a plurality of sheets having a conductive pattern formed thereon and a capacitor sheet in which copper electrodes are formed on upper and lower surfaces of a sheet of high-k dielectric material are stacked and sintered to form a package substrate including an embedded-type capacitor. However, because it is difficult to form the conductive pattern in a fine pattern or the thickness of the high-k dielectric material sheet is relatively large, it is difficult to realize high capacitance. In addition, in the process of forming a package substrate by lamination and sintering of sheets, misalignment between the upper electrode and the lower electrode can easily occur, so there is a problem in that the capacitance of the built-in capacitor is difficult to precisely control (e.g., a relatively large capacitance deviation occurs).

However, according to an example embodiment, the lower electrode layer LE may be formed by a sintering process of the ceramic substrate 110, and the upper electrode layer UE may be formed by an electrolytic plating or an electroless plating process capable of forming a finer pattern than that of the lower electrode layer LE. Accordingly, the upper electrode layer UE may be formed to have a precise pattern shape based on required capacitance. Accordingly, misalignment between the lower electrode layer LE and the upper electrode layer UE may be prevented, and capacitance deviation of the capacitor structure 130 may be prevented.

In addition, according to an example embodiment, because the capacitor structure 130 includes the dielectric layer DL having a relatively thin thickness, the capacitor structure 130 may exhibit high capacitance. Also, in the ceramic substrate 110, because the difference in the coefficient of thermal expansion with the silicon interposer is small, warpage or bending can be prevented in the process of mounting the silicon interposer on the package substrate 100. In addition, because the ceramic substrate 110 has relatively high thermal conductivity, the ceramic substrate 110 may have excellent heat dissipation characteristics.

In addition, according to an example embodiment, the lower electrode layer LE may be formed in the process for forming the ceramic substrate 110, and the upper electrode layer UE may be formed in the process for forming the redistribution structure 120. Accordingly, a manufacturing cost may be reduced compared to a case in which a trench is formed in a silicon substrate, such as an interposer, and an embedded decoupling capacitor is formed in the trench.

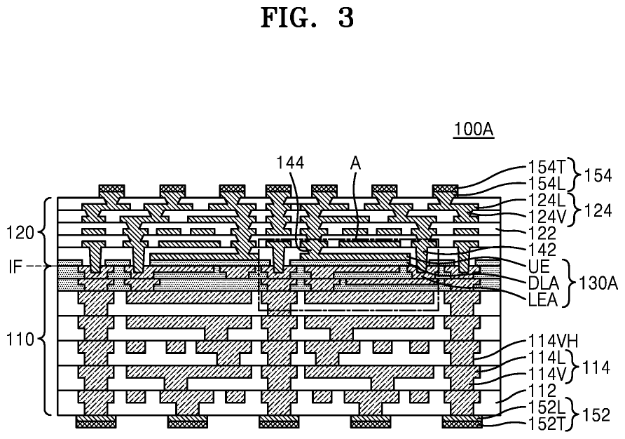

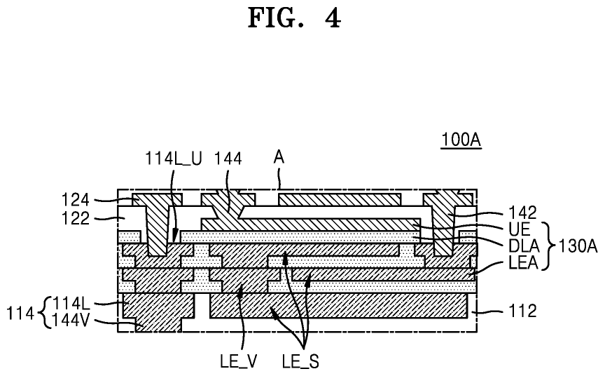

FIG. 3 is a cross-sectional view illustrating a package substrate 100A according to an example embodiment. FIG. 4 is an enlarged view of part A of FIG. 3 according to an example embodiment.

Referring to FIGS. 3 and 4, the package substrate 100A may include a capacitor structure 130A provided at the interface IF between the ceramic substrate 110 and the redistribution structure 120, and the capacitor structure 130A may be a thin film decoupling capacitor having a multilayer MIM structure.

The capacitor structure 130A may include a lower electrode layer LEA, a dielectric layer DLA, and an upper electrode layer UE.

The lower electrode layer LEA may have a multilayer structure, for example, and may include a plurality of lower electrode segments LE_S disposed at different vertical levels. Each of the plurality of lower electrode segments LE_S may have a flat plate shape extending in a horizontal direction. For example, FIGS. 3 and 4 illustrate an example embodiment in which the lower electrode layer LEA is formed in a three-layer structure and the lower electrode layer LEA includes the plurality of lower electrode segments LE_S disposed at three different vertical levels, but, according to an example embodiment, the lower electrode layer LEA may be formed to include the plurality of lower electrode segments LE_S disposed on two or four or more vertical levels.

The lower electrode layer LEA may further include a via segment LE V connecting the plurality of lower electrode segments LE_S disposed at different vertical levels. For example, the via segment LE V may be disposed between two adjacent lower electrode segments LE_S to provide an electrical connection therebetween.

The dielectric layer DLA may be disposed between the lower electrode layer LEA and the upper electrode layer UE and between the plurality of lower electrode segments LE_S of the lower electrode layer LEA. For example, as the dielectric layer DLA is disposed between the lower electrode layer LEA and the upper electrode layer UE and between the plurality of lower electrode segments LE_S of the lower electrode layer LEA, the effective area of the capacitor structure 130A may increase, and thus the capacitor structure 130A may exhibit increased capacitance.

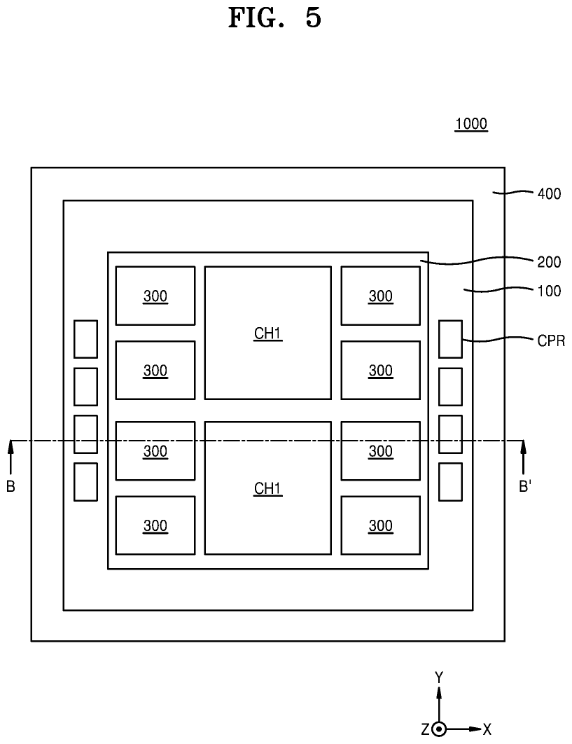

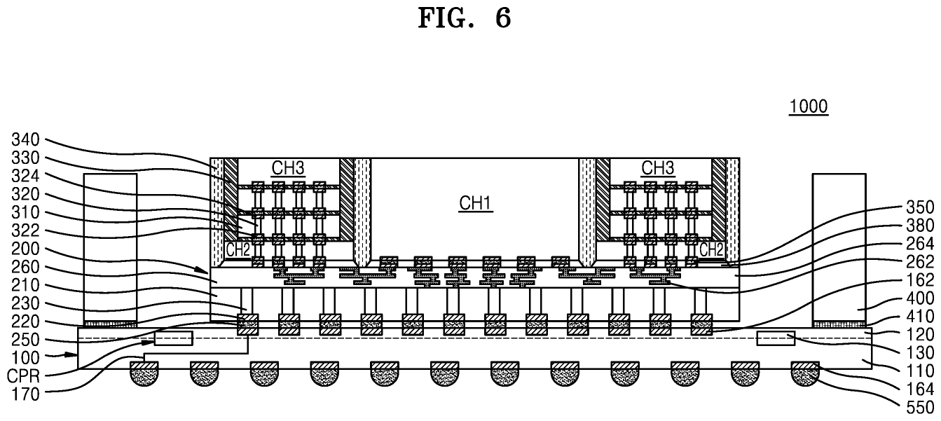

FIG. 5 is a planar layout illustrating a semiconductor package 1000 according to an example embodiment, and FIG. 6 is a cross-sectional view taken along line B-B′ of FIG. according to an example embodiment.

Referring to FIGS. 5 and 6, the semiconductor package 1000 may include a package substrate 100, an interposer 200 attached to the package substrate 100, a plurality of first semiconductor chips CH1 attached to the interposer 200, and at least one stacked structure 300 attached to the interposer 200. The at least one stack structure 300 and the plurality of first semiconductor chips CH1 may be spaced apart from each other in a horizontal direction and may be attached to the interposer 200.

In FIG. 1, the semiconductor package 1000 is illustrated as including eight stacked structures 300 attached on the interposer 200, but an example embodiment is not limited thereto. For example, the semiconductor package 1000 may include one, two, four, six, eight, or more stacked structures 300. The stacked structure 300 may be referred to as a memory stack.

At least some of the plurality of first semiconductor chips CH1 may be logic semiconductor chips. At least some of the plurality of first semiconductor chips CH1 may include, for example, a central processing unit (CPU) chip, a graphics processing unit (GPU) chip, and an application processor (AP), an application specific integrated circuit (ASIC), or other processing chips.

As described with reference to FIGS. 1 and 2, the package substrate 100 may include a ceramic substrate 110 and a redistribution structure 120. A capacitor structure 130 may be disposed in the decoupling capacitor region CPR of the package substrate 100. For example, the capacitor structure 130 may be provided at an interface between the ceramic substrate 110 and the redistribution structure 120.

The package substrate 100 may include a plurality of board upper surface pads 162 and a plurality of board lower surface pads 164 respectively disposed on an upper surface and a lower surface thereof. The package substrate 100 may include a plurality of board wiring paths 170 that electrically connect the plurality of upper surface pads 162 and the plurality of board lower surface pads 164 to each other through the ceramic substrate 110 and the redistribution structure 120.

A plurality of package connection terminals 250 may be connected to the plurality of board upper surface pads 162, and a plurality of external connection terminals 550 may be connected to the plurality of board lower surface pads 164. The plurality of package connection terminals 250 may electrically connect between the interposer 200 and the package substrate 100. The plurality of external connection terminals 550 connected to the plurality of board bottom pads 164 may connect the semiconductor package 1000 to the outside. In some example embodiments, each of the plurality of package connection terminals 250 and the plurality of external connection terminals 550 may be a bump, a solder ball, or the like.

The interposer 200 may be used to implement a vertical connection terminal in a fine pitch type for interconnecting at least one stacked structure 300 and the plurality of first semiconductor chips CH1 to the package substrate 100. The interposer 200 includes a base layer 210, a plurality of interposer lower surface pads 220 disposed on a lower surface of the base layer 210, a plurality of interposer through electrodes 230 penetrating the base layer 210 to connect between the upper surface and the lower surface of the base layer 210, and an interposer interconnection structure 260 disposed on the upper surface of the base layer 210. A plurality of interposer connection terminals 250 may be attached to the plurality of interposer lower surface pads 220. The plurality of interposer connection terminals 250 may be interposed between the plurality of board upper surface pads 162 and the plurality of interposer lower surface pads 220 to electrically connect the interposer 200 and the package substrate 100.

The base layer 210 may include a semiconductor material, glass, ceramic, or plastic. For example, the base layer 210 may include silicon. In some example embodiments, the interposer 200 may be a silicon interposer in which the base layer 210 is formed from a silicon semiconductor substrate.

Each of the plurality of interposer through electrodes 230 may include a conductive plug penetrating through the base layer 210 and a conductive barrier layer surrounding the conductive plug. The conductive plug may include Cu or W, and the conductive barrier layer may include a metal or a conductive metal nitride. The conductive plug may have a cylindrical shape, and the conductive barrier layer may have a cylindrical shape surrounding a sidewall of the conductive plug. A plurality of via insulating layers may be interposed between the base layer 210 and the plurality of interposer through electrodes 230 to surround sidewalls of the plurality of interposer through electrodes 230. The plurality of via insulating layers may prevent direct contact between the base layer 210 and the plurality of interposer through electrodes 230. The via insulating layer may be formed of an oxide layer, a nitride layer, a carbide layer, a polymer, or a combination thereof.

The interposer interconnection structure 260 may include a plurality of interposer wiring line patterns 262 and an interposer wiring insulating layer 264. In some example embodiments, the interposer interconnection structure 260 may be formed through a redistribution process.

The interposer wiring line pattern 262 may be, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof, but is not limited thereto. The interposer wiring insulating layer 264 may be formed of, for example, a photo-imageable dielectric (PID) or a photosensitive polyimide (PSPI). In some example embodiments, the interposer wiring structure 260 may include a plurality of stacked interposer wiring insulating layers 264.

In some other example embodiments, the interposer interconnection structure 260 may be formed by a semiconductor back end of line (BEOL) process. The interposer wiring line pattern 262 may include a metal material such as copper (Cu), aluminum (Al), and tungsten (W). The interposer wiring insulating layer 264 may include a high density plasma (HDP) oxide film, a Tetraethyl orthosilicate (TEOS) oxide film, Tonen silazene (TOSZ), spin on glass (SOG), undoped silica glass (USG), a low-k dielectric layer, or the like.

Some of the plurality of interposer wiring line patterns 262 disposed on the upper surface of the interposer 200 may be referred to as interposer upper surface pads. A plurality of chip connection terminals 350 may be attached to the interposer upper surface pad, and the plurality of chip connection terminals 350 may be disposed between the interposer 200 and the stacked structure 300 and between the interposer 200 and the first semiconductor chip CH1. In some example embodiments, the plurality of chip connection terminals 350 may be bumps, solder balls, or the like. An underfill layer 380 surrounding the plurality of chip connection terminals 350 may be interposed between the interposer 200 and the stacked structure 300 and between the interposer 200 and the first semiconductor chip CH1. The underfill layer 380 may be formed of, for example, an epoxy resin formed by a capillary underfill method. In some example embodiments, the underfill layer 380 may be a non-conductive film (NCF).

The stacked structure 300 may include a second semiconductor chip CH2 and a plurality of third semiconductor chips CH3. In some example embodiments, one stacked structure 300 may include a multiple of 4 third semiconductor chips CH3. The plurality of third semiconductor chips CH3 may be sequentially stacked on the second semiconductor chip CH2 in a vertical direction. Each of the second semiconductor chip CH2 and the plurality of third semiconductor chips CH3 may be sequentially stacked with an active surface facing the lower side, that is, the interposer 200.

The second semiconductor chip CH2 and the plurality of third semiconductor chips CH3 may be a dynamic random access memory (DRAM), a static random access memory (SRAM), a flash memory, an electrically erasable and programmable read-only memory (EEPROM), a phase-change random access memory (PRAM), a magnetic random access memory (MRAM), or a resistive random access memory (RRAM).

In some example embodiments, the second semiconductor chip CH2 may not include a memory cell. The second semiconductor chip CH2 may include a serial-parallel conversion circuit, a test logic circuit, such as a design for test (DFT), a joint test action group (JTAG) test, and a memory built-in self-test (MBIST), and a signal interface circuit, such as a physical (PHY) interface. The plurality of third semiconductor chips CH3 may include memory cells. For example, the second semiconductor chip CH2 may be a buffer chip for controlling the plurality of third semiconductor chips CH3.

In some example embodiments, the second semiconductor chip CH2 may be a buffer chip for controlling the High-bandwidth memory (HBM) DRAM, and the plurality of third semiconductor chips CH3 may be memory cell chips including HBM DRAM cells controlled by the second semiconductor chip CH2. The second semiconductor chip CH2 may be referred to as a buffer chip or a master chip, and the third semiconductor chip CH3 may be referred to as a slave chip or a memory cell chip. The stacked structure 300 including the second semiconductor chip CH2 and a plurality of third semiconductor chips CH3 sequentially stacked on the second semiconductor chip CH2 may be referred to as an HBM DRAM device.

Each of the second semiconductor chip CH2 and the third semiconductor chip CH3 may include a substrate 310, a plurality of through electrodes 320, a plurality of first front connection pads 322, and a plurality of first rear connection pads 324. The substrate 310 may include silicon (Si). Alternatively, the substrate 310 may include a semiconductor element such as germanium (Ge), or a compound semiconductor, such as silicon carbide (SiC), gallium arsenide (GaAs), indium arsenide (InAs), and indium phosphide (InP). The substrate 310 may have the active surface and an inactive surface opposite to the active surface. The substrate 310 may include a plurality of individual devices of various types on the active surface. The plurality of individual devices may include various microelectronic devices, for example, a metal-oxide-semiconductor field effect transistor (MOSFET) such as a complementary metal-oxide-semiconductor (CMOS) transistor, a system large scale integration (LSI), an image sensor such as a CMOS imaging sensor (CIS), a micro-electro-mechanical system (MEMS), active devices, passive devices, and the like.

The plurality of through electrodes 320 may vertically penetrate at least a portion of the substrate 310 to electrically connect the plurality of first front connection pads 322 and the plurality of first rear connection pads 324.

The stacked structure 300 may further include a chip molding layer 330 surrounding the plurality of third semiconductor chips CH3 on the upper surface of the second semiconductor chip CH2. The chip molding layer 330 may cover an upper surface of the second semiconductor chip CH2 and may cover side surfaces of the plurality of third semiconductor chips CH3. In some example embodiments, the chip molding layer 330 may cover the side surfaces of the plurality of third semiconductor chips CH3, but may expose the upper surface of the third semiconductor chips CH3, that is, the non-active surface of the third semiconductor chip CH3 positioned at the top without covering it. The chip molding layer 330 may be formed of, for example, Epoxy Molding Compound (EMC)

The semiconductor package 1000 may further include a package molding layer 340 surrounding the at least one stacked structure 300 and the plurality of first semiconductor chips CH1 on the interposer 200. The package molding layer 620 may be formed of, for example, EMC. In some example embodiments, the package molding layer 620 may not cover the upper surface of the third semiconductor chip CH3 positioned at the top and the upper surface of the plurality of first semiconductor chips CH1. In some example embodiments, the package molding layer 340 may surround side surfaces of the chip molding layer 330 surrounding the plurality of third semiconductor chips CH3 included in at least one stacked structure 300 and side surfaces of the second semiconductor chip CH2 included in the at least one stacked structure 300.

The semiconductor package 1000 may further include a stiffener structure 400 attached to the package substrate 100. The stiffener structure 400 may be attached to the package substrate 100 having a stiffener thermal interface material 410 between the reinforcement structure 400 and the package substrate 100. The stiffener structure 400 may be disposed to be spaced apart from the stacked structure 300 and the first semiconductor chip CH1. In some example embodiments, the stiffener structure 400 may be attached on the package substrate 100 to be spaced apart from the interposer 200. The stiffener structure 400 may extend along an edge of the package substrate 100 in a plan view, that is, in a top view, and surround the stacked structure 300 and the first semiconductor chip CH1.

The stiffener structure 400 may be made of metal. For example, the stiffener structure 400 may include at least one of copper, nickel, and stainless steel. The stiffener heat transfer material layer 410 may be made of an insulating material or a material capable of maintaining electrical insulation including an insulating material. The stiffener heat transfer material layer 410 may include, for example, an epoxy resin. The stiffener heat transfer material layer 410 may be, for example, mineral oil, grease, gap filler putty, phase change gel, phase change material pads, or a particle filled epoxy. For example, the stiffener structure 400 may have a vertical height of about 500 μm to about 800 μm.

In the semiconductor package 1000 according to example embodiments, the package substrate 100 may include a capacitor structure 130 formed in the decoupling capacitor formation region CPR, and the first semiconductor chip CH1 and the plurality of stacked structures 300 may be mounted on the package substrate 100 through the interposer 200. According to the semiconductor package according to the comparative example, the interposer may form a trench in the interposer substrate by using an etching process and may include a built-in decoupling capacitor disposed in the trench, but manufacturing cost may increase by the etching process. On the other hand, according to an example embodiment, because the capacitor structure 130 may be formed in the process of forming the ceramic substrate 110 and the redistribution structure 120 of the package substrate 100, manufacturing cost may be reduced.

In addition, because the ceramic substrate 110 has a small difference in the coefficient of thermal expansion compared to the interposer 200, warpage or bending may be prevented in the process of mounting the interposer 200 on the package substrate 100. Because the ceramic substrate 110 has relatively high thermal conductivity, heat generated from the semiconductor chip CH1 or the stacked structure 300 may be rapidly transferred or discharged through the package substrate 100.

FIGS. 5 and 6 illustrate an example embodiment wherein the semiconductor package 1000 includes the package substrate 100 described with reference to FIGS. 1 and 2, but in other example embodiments, the semiconductor package 1000 may include the package substrate 100A described with reference to FIGS. 3 to 4.

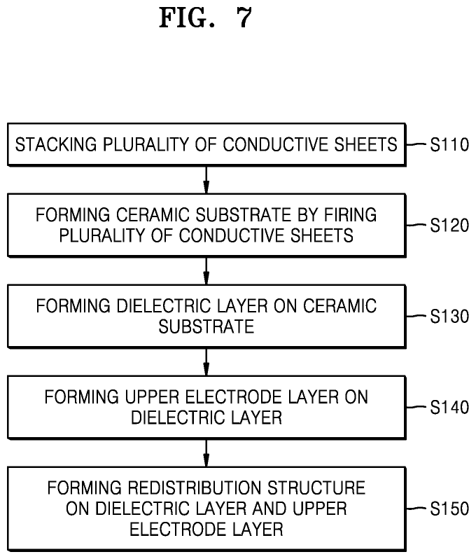

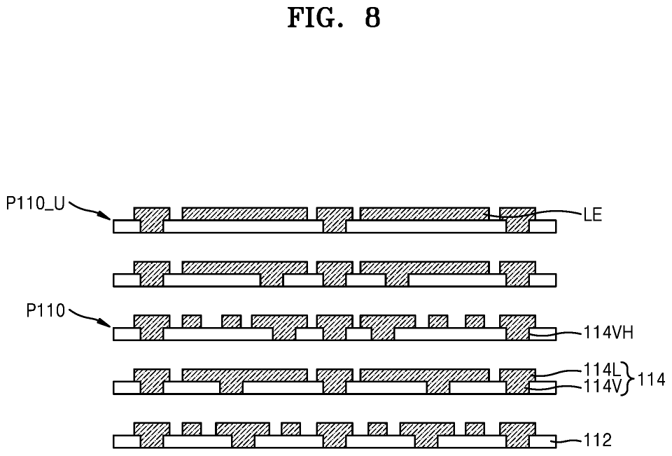

FIG. 7 is a flowchart illustrating a method of manufacturing a package substrate 100 according to an example embodiment. FIGS. 8, 9, 10 11 and 12 are cross-sectional views illustrating a method of manufacturing a package substrate 100 according to example embodiments.

Referring to FIGS. 7 and 8, in operation S110, according to an example embodiment, a plurality of conductive sheets may be stacked.

In an example embodiment, each of the plurality of conductive sheets P110 may include a first insulating layer 112, a first wiring layer 114L disposed on the upper surface of the first insulating layer 112, and a first via 114V disposed in a via hole 114VH passing through the first insulating layer 112.

An uppermost conductive sheet P110_U may include the lower electrode layer LE disposed on=vertical level as the first wiring layer 114L.

In an example embodiment, the first insulating layer 112 may be formed using a low-temperature-fired dielectric material, and may include, for example, aluminum oxide (Al₂O₃). In an example embodiment, the lower electrode layer LE and the first wiring layer 114L may be formed using a first conductive material, and the first conductive material may include silver or tungsten. In an example embodiment, the lower electrode layer LE and the first wiring layer 114L may be formed by applying or printing silver paste on the first insulating layer 112.

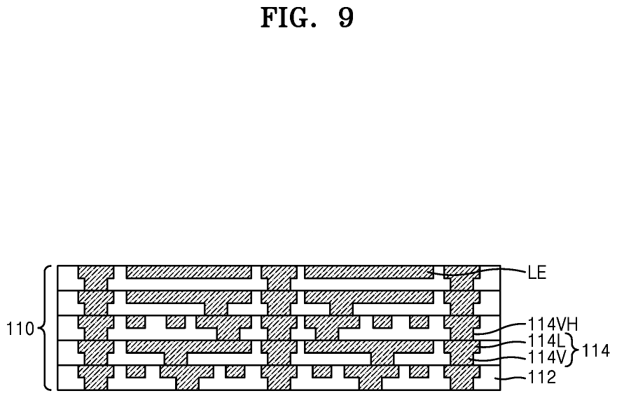

Referring to FIGS. 7 and 9, in operation S120, the ceramic substrate 110 may be formed by firing or sintering the plurality of conductive sheets P110.

In an example embodiment, the firing temperature or the sintering temperature of the plurality of conductive sheets P110 may be about 700° C. to about 1100° C. In an example embodiment, the first wiring layer 114L and the first via 114V stacked in the vertical direction in the firing process may constitute the first circuit wiring layer 114.

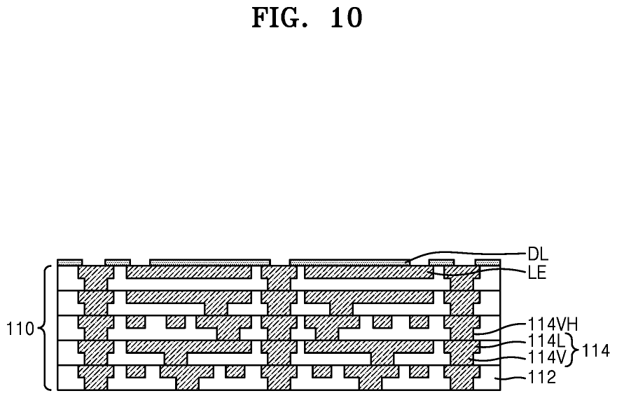

Referring to FIGS. 7 and 10, in operation S130, a dielectric layer DL may be formed on the ceramic substrate 110.

In an example embodiment, the dielectric layer DL may be formed by at least one of a chemical vapor deposition (CVD) process and a physical vapor deposition (PVD) process, an atomic layer deposition (ALD) process, a spin coating process, and a spray process, using a high-k dielectric material.

In some example embodiments, the dielectric layer DL may include a material having a dielectric constant of about 5 or more, or about 10 or more. For example, the dielectric layer DL may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or combinations thereof, but is not limited thereto.

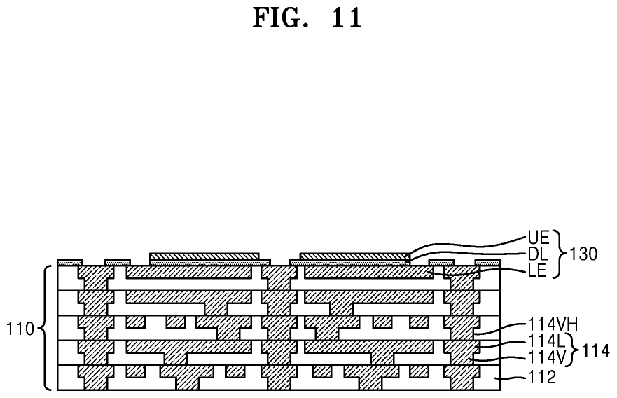

Referring to FIGS. 7 and 11, in operation S140, an upper electrode layer UE may be formed on the dielectric layer DL.

In an example embodiment, the upper electrode layer UE may be formed using a second conductive material, and the second conductive material may include at least one of copper, nickel, gold, platinum, titanium, chromium, or an alloy thereof.

In an example embodiment, the upper electrode layer UE may be formed on the upper surface of the dielectric layer DL by using at least one of an electrolytic plating process, an electroless plating process, a sputtering process, and an evaporation process. The upper electrode layer UE may be formed using a process capable of forming a finer pattern than that of the lower electrode layer LE.

Accordingly, the capacitor structure 130 of the MIM structure including the lower electrode layer LE, the dielectric layer DL, and the upper electrode layer UE may be formed.

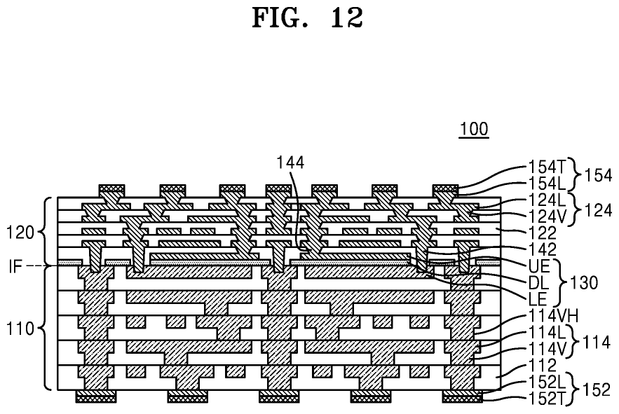

Referring to FIGS. 7 and 12, in operation S150, the redistribution structure 120 including the second circuit wiring layer 124 may be formed on the dielectric layer DL and the upper electrode layer UE.

In an example embodiment, in order to form the redistribution structure 120, the forming the plurality of second insulating layers 122 and the forming the plurality of second wiring layers 124L may be repeatedly performed.

In an example embodiment, the second insulating layer 122 may be formed using a polymer material, for example, a photo-imageable dielectric (PID), a photosensitive polyimide (PSPI), glass fiber-cured epoxy resins, polyimide resins, teflon resins, and the like. In some example embodiments, the forming of the plurality of second wiring layers 124L may be performed using at least one of an electrolytic plating process, an electroless plating process, a sputtering process, and an evaporation process.

For example, in the forming of the redistribution structure 120, through the process of forming the plurality of second wiring layers 124L, a second via 124V for connecting the second wiring layers 124L disposed at different vertical levels may be formed. For example, a via hole (not shown) may be formed in the second insulating layer 122, a second wiring layer 124L may be formed on the second insulating layer 122, and a portion of the second wiring layer 124L filling the inside of the via hole may be referred to as a second via 124V.

In an example embodiment, the forming of the lowermost second wiring layer 124L or the forming of the lowermost second via 124V may be performed simultaneously with the forming of the upper electrode layer UE.

Thereafter, a first pad 152 electrically connected to the first circuit wiring layer 114 may be formed on the bottom surface of the ceramic substrate 110, and a second pad 154 electrically connected to the second circuit wiring layer 124 may be formed on the upper surface of the redistribution structure 120.

According to an example embodiment, the upper electrode layer UE may be formed by an electrolytic plating process, an electroless plating process, plating processes, sputtering process, or evaporation process, which is capable of forming a finer pattern compared to the lower electrode layer LE, and thus may be formed to have a precise pattern shape based on the required capacitance. Accordingly, misalignment between the lower electrode layer LE and the upper electrode layer UE may be prevented, and capacitance deviation of the capacitor structure 130 may be prevented. In addition, the lower electrode layer LE may be formed in the process for forming the ceramic substrate 110, and the upper electrode layer UE may be formed in the process for forming the redistribution structure 120. Accordingly, manufacturing cost may be reduced compared to a case in which a trench is formed in a silicon substrate such as an interposer and an embedded decoupling capacitor is formed in the trench.

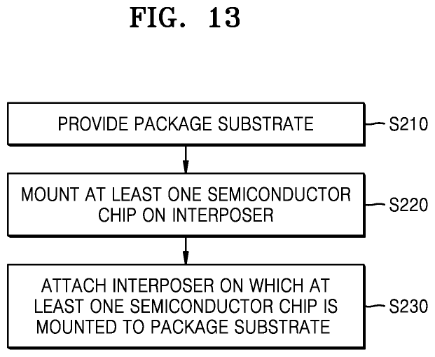

FIG. 13 is a flowchart illustrating a method of manufacturing a semiconductor package according to an example embodiment.

Referring to FIG. 13, in operation S210, a package substrate may be provided.

The providing of the package substrate may be the same as or similar to the method of manufacturing the package substrate described with reference to example embodiments shown in FIGS. 7, 8, 9, 10, 11 and 12.

Thereafter, in operation S220, at least one semiconductor chip may be mounted on the interposer.

In an example embodiment, the at least one semiconductor chip may be at least one first semiconductor chip CH1 and/or at least one stacked structure 300 included in the semiconductor package 1000 described with reference to FIGS. 5 and 6, and the at least one stacked structure 300 may include at least one second semiconductor chip CH2 and a plurality of third semiconductor chips CH3 stacked on the second semiconductor chip CH2.

Thereafter, in operation S230, an interposer on which at least one semiconductor chip is mounted may be attached to the package substrate.

While example embodiments have been particularly shown and described above, it will be apparent to those skilled in the art that various changes in form and details may be made therein without departing from the spirit and scope as defined by the following claims.

1. A package substrate comprising:
a ceramic substrate comprising:
a plurality of first insulating layers; and
a first circuit wiring layer disposed in the plurality of first insulating layers;
a redistribution structure disposed on an upper surface of the ceramic substrate, the redistribution structure comprising:
a plurality of second insulating layers; and
a second circuit wiring layer disposed in the plurality of second insulating layers and electrically connected to the first circuit wiring layer; and
a capacitor structure provided at an interface between the ceramic substrate and the redistribution structure, the capacitor structure comprising:
a lower electrode layer disposed at a same vertical level as at least a portion of the first circuit wiring layer;
a dielectric layer disposed between the ceramic substrate and the redistribution structure; and
an upper electrode layer disposed on an upper surface of the dielectric layer.

2. The package substrate of claim 1, wherein the lower electrode layer comprises a first conductive material, and
wherein the upper electrode layer includes a second conductive material different from the first conductive material.

3. The package substrate of claim 1, wherein the lower electrode layer comprises a same material as the first circuit wiring layer, and
wherein the upper electrode layer includes a same material as the second circuit wiring layer.

4. The package substrate of claim 1, wherein the lower electrode layer comprises silver or tungsten, and
wherein the upper electrode layer comprises at least one of copper, nickel, gold, platinum, titanium, chromium, or an alloy thereof.

5. The package substrate of claim 1, wherein the redistribution structure further comprises:
a first bump connection via connected to the lower electrode layer through one of the plurality of second insulating layers, and
a second bump connection via connected to the upper electrode layer through the one of the plurality of second insulating layers.

6. The package substrate of claim 5, wherein each of the first bump connection via and the second bump connection via has a first width in a range of about 20 micrometers to about 60 micrometers, and
wherein the dielectric layer has a thickness in a range of about 1 micrometer to about 5 micrometers.

7. The package substrate of claim 1, wherein the lower electrode layer comprises a plurality of lower electrode segments disposed at different vertical levels, and
wherein the dielectric layer is disposed between two adjacent ones of the plurality of lower electrode segments and between an uppermost lower electrode segment and the upper electrode layer.

8. The package substrate of claim 1, wherein the first circuit wiring layer comprises:
a plurality of wiring layers disposed at different vertical levels; and
a plurality of vias connecting the plurality of wiring layers disposed at different vertical levels, and
wherein the lower electrode layer is disposed on a same vertical level as an uppermost wiring layer among the plurality of wiring layers.

9. The package substrate of claim 8, wherein the dielectric layer covers upper surfaces of the uppermost wiring layer and the lower electrode layer.

10. A semiconductor package comprising:
a package substrate;
an interposer disposed on the package substrate; and
at least one semiconductor chip disposed on the interposer,
wherein the package substrate comprises:
a ceramic substrate comprising:
a plurality of first insulating layers; and
a first circuit wiring layer disposed in the plurality of first insulating layers;
a redistribution structure disposed on an upper surface of the ceramic substrate, the redistribution structure comprising:
a plurality of second insulating layers; and
a second circuit wiring layer disposed in the plurality of second insulating layers and electrically connected to the first circuit wiring layer; and
a capacitor structure provided at an interface between the ceramic substrate and the redistribution structure, the capacitor structure comprising:
a lower electrode layer disposed at a same vertical level as at least a portion of the first circuit wiring layer;
a dielectric layer disposed between the ceramic substrate and the redistribution structure; and
an upper electrode layer disposed on an upper surface of the dielectric layer.

11. The semiconductor package of claim 10, wherein the lower electrode layer comprises a first conductive material, and
wherein the upper electrode layer includes a second conductive material different from the first conductive material.

12. The semiconductor package of claim 10, wherein the lower electrode layer comprises a same material as the first circuit wiring layer, and
wherein the upper electrode layer comprises a same material as the second circuit wiring layer.

13. The semiconductor package of claim 10, wherein the lower electrode layer comprises silver or tungsten, and
wherein the upper electrode layer comprises at least one of copper, nickel, gold, platinum, titanium, chromium, or an alloy thereof.

14. The semiconductor package of claim 10, wherein the redistribution structure further comprises:
a first bump connection via connected to the lower electrode layer; and
a second bump connection via connected to the upper electrode layer,
wherein each of the first bump connection via and the second bump connection via has a first width in a range of about 20 micrometers to about 60 micrometers.

15. The semiconductor package of claim 10, wherein the dielectric layer has a thickness in a range of about 1 micrometer to about 5 micrometers.

16. The semiconductor package of claim 10, wherein the first circuit wiring layer comprises:
a plurality of wiring layers disposed at different vertical levels; and
a plurality of vias connecting the plurality of wiring layers disposed at different vertical levels, and
wherein the lower electrode layer is disposed on a same vertical level as an uppermost wiring layer among the plurality of wiring layers.

17. A semiconductor package comprising:
a package substrate;
an interposer disposed on the package substrate;
at least one first semiconductor chip disposed on the interposer; and
at least one stacked structure disposed on the interposer,
wherein the package substrate comprises:
a ceramic substrate comprising:
a plurality of first insulating layers; and
a first circuit wiring layer disposed in the plurality of first insulating layers;
a redistribution structure disposed on an upper surface of the ceramic substrate, the redistribution structure comprising:
a plurality of second insulating layers; and
a second circuit wiring layer disposed in the plurality of second insulating layers and electrically connected to the first circuit wiring layer; and
a capacitor structure provided at an interface between the ceramic substrate and the redistribution structure, the capacitor structure comprising:
a lower electrode layer disposed on a same vertical level as at least a portion of the first circuit wiring layer and including a first conductive material;
a dielectric layer disposed between the ceramic substrate and the redistribution structure; and
an upper electrode layer disposed on an upper surface of the dielectric layer and including a second conductive material different from the first conductive material, and
wherein the at least one stacked structure comprises:
a second semiconductor chip comprising a through electrode; and
a plurality of third semiconductor chips stacked on the second semiconductor chip in a vertical direction, each of the third semiconductor chips comprising a through electrode.

18. The semiconductor package of claim 17, wherein the first conductive material comprises silver or tungsten, and
wherein the second conductive material comprises at least one of copper, nickel, gold, platinum, titanium, chromium, or an alloy thereof.

19. The semiconductor package of claim 17, wherein the first semiconductor chip is a logic semiconductor chip, and
wherein the plurality of third semiconductor chips is a memory cell chip.

20. The semiconductor package of claim 17, wherein the first circuit wiring layer comprises the first conductive material, and
wherein the second circuit wiring layer comprises the second conductive material.

21.-30. (canceled)
